(19) United States
(12) Patent Application Publication
(10) Pub. No.: US 2011/0089938 A1
(43) Pub. Date: Apr. 21, 2011

(54) Device and Method for the Detection of Electrically Conducting Objects

(75) Inventor: Ralf Philipp Schmidt, Freinsheim (DE)

(73) Assignee: iCONTROLS, k.s., Bratislava (SK)

(21) Appl. No.: 12/906,637

(22) Filed: Oct. 18, 2010

(30) Foreign Application Priority Data
Oct. 19, 2009 (DE) 102009049821.4

(51) Int. Cl. G01R 33/12

(52) U.S. Cl. 324/239

(57) ABSTRACT

The invention relates to a device for the detection of electrically conducting objects with: a first and a second coil, which can produce simultaneously magnetic fields with opposite polarity and a third coil which is arranged in the region of the opposing magnetic fields, and an electronic means, which during and/or after the supply of the first and second coils with a current pulse acquires an induction voltage in the third coil, or which, during the supply of the third coil with a current pulse, acquires an induction voltage in the first and second coils, so that an electrically conducting object produces a detectable signal in the acquired induction voltage when present in the range of one of the magnetic fields, wherein the current pulse comprises a step-shaped rise and/or a step-shaped fall, such as for example in the shape of a rectangular pulse.

The invention relates to a device and method for the detection of electrically conducting objects.

An inductive proximity switch is known from DE 41 02 542 A1. This inductive proximity switch contains an oscillator, which generates a magnetic alternating field and which changes its oscillatory state when a tripping device penetrates the alternating field, which is used by an evaluation circuit for obtaining a switching signal for the actuation of a load switch. The measurable change in the oscillatory state depends both on the typical material characteristics of the tripping device and its distance and position relative to the switch. These switches thus react relatively non-specifically to various materials and essentially only at the distance between the tripping device and the switch.

From DE 39 34 593 C2 a sensor is known in which a triangular signal is applied to the primary coil so that according to the law of induction a rectangular signal with the frequency of the triangular signal is produced on the output of the secondary coil. This variant is used to design a sensor which supplies a dependable signal. This is achieved by the continuous rise and fall according to the triangular signal.

Furthermore, from EP 0 936 741 A1 an inductive proximity switch is known, which uses a single coil, which, by means of a transmitted current pulse, generates an induction voltage in the body to be acquired, which causes a current in the body, the decay of which after the end of the current pulse induces a voltage in the coil, which can be processed appropriately. The transmitted current pulses lie in the range between 100 μs and 200 μs. With this method the same coil is used for producing an eddy current as for acquiring the decaying eddy current. A metal housing for this sensor must not be ferromagnetic and must exhibit a relatively high specific electrical resistance.

The object of the invention is to provide a device and a method with which specific special features of the object to be acquired, such as for example material properties, material composition or the size of the object can be detected, preferably (essentially) independently of the distance between the device and the object.

This object is solved with a device according to claim 1 and a method according to claim 12. Preferred embodiments are disclosed in the dependent claims.

The device has three coils, of which two can be used for producing magnetic fields and one for the detection of a voltage or, vice versa, one for producing the magnetic field and two for the detection of an induction voltage. Furthermore, the device has an electronic means, which acquires an induction voltage (especially) during and/or after the supply of a current pulse to the coil producing the magnetic field. If an electrically conducting object is located in the range of the magnetic field, it produces a detectable signal in the acquired induction voltage. Depending on the material properties and size of the detected object, the acquired induction voltage can exhibit specific characteristics. From these, conclusions can be drawn about the material of the object, the material composition of the object and/or the size of the object.

The first and second coils can be wound in opposite directions or the same direction. The two coils can be separated spatially from one another. By connecting these coils appropriately, magnetic fields with opposite polarity can be produced. The first and second coils can be connected in series. They can also however each be supplied (independently of one another) from a current source.

On both sides of the coil system (comprising the first, second and third coil) electrically conducting objects produce signal shapes with opposite signs so that the same effects on both sides are mutually eliminating.

The current pulse preferably has a step-shaped rise and/or a step-shaped fall, such as for example with a rectangular pulse. In a preferred embodiment the current pulse has the shape of a rectangular pulse and a duration between 0.1 ns and 1 ms, such as approximately between 1 μs and 50 μs. The shorter the current pulse is or the shorter the rise or fall, the higher the frequency of the excitation spectrum for the eddy current. Through portions with different frequencies different size scales of the object can, in particular, be differentiated as well as frequency-specific material properties and thus conclusions can be drawn about the composition of the electrically conducting object. The rise time, in which for example 90% of the maximum current value (of the step-shaped rise) can be achieved and/or the decay time in which the current falls from the initial value to 10% of the step-shaped drop, can be shorter than 0.2 or 0.1 μs.

The induction effect in the third coil produced by the first and second coils or the induction effect produced by the third coil in the first and second coils cancel one another at least partially. Preferably, this occurs by at least 90% or 99%. The compensation effect can be such that with the absence of the electrically conducting object to be detected, the acquired induction voltage is essentially zero. This leads to a higher sensitivity of the device for detection, because each presence of an electrically conducting object produces an induction voltage not equal to zero or an induction voltage which differs from a reference voltage.

If the induction voltage produced in the first and second coils is acquired, then these two coils are preferably connected such that the induction voltages compensate one another, at least partially, preferably by at least 90% or 99%, whereby preferably the compensation occurs such that with the absence of an electrically conducting object to be detected the two induction voltages essentially sum to zero.

Preferably the course of the produced induction voltage is acquired at various times (time-dependent acquisition), during and/or after the current pulse. Thus, for each current pulse, for example, more or less than five, more or less than ten or more or less than one hundred measurements can be acquired.

In a particularly preferred embodiment one, two, three or more maximum and/or minimum and/or reversing points and/or zero crossovers (characteristic points) of the acquired induction voltage are determined in the time-dependent acquired course of the induction voltage. As the criterion for the evaluation of the detection of an electrically conducting object, the time interval between the maximum and/or minimum and/or reversing point and/or a zero crossover can be determined, for example. These signals have the advantage that they are essentially independent of the distance between the device and the electrically conducting object to be detected.

The signal level is different at different distances, but the times, for example, between maximum/minimum and zero crossover are (essentially) independent of the distance. Also, several characteristic points can be determined for a current pulse, such as one maximum and one minimum or several maxima or several minima or several zero crossovers. Here, several time intervals between several (in this case at least three) characteristic points of this nature can be determined and/or the times between the start of the current pulse and the several characteristic points.

Also the duration from the beginning of a current pulse to the reaching of a maximum/minimum value or a zero crossover or a reversing point can be employed to characterise the electrically conducting object detected.

Also a differentiation between small and large objects is possible with criteria of this nature. For example, metal particles produced by welding splashes can be differentiated from large electrically conducting objects, such as for example, metal plates in order to detect a malfunction of the sensors or dirt deposition on them.

In addition or alternatively to temporally determined characteristics of this nature, other characteristics, such as for example, absolute values for a maximum/minimum or reversing point can be used.

In the region of the first or second coils one, two, or more metallic conducting objects can be provided as constituent parts of the device. With these/this object(s), balancing of the induction voltage produced is possible and/or also the specification of a reference object. To balance the produced induction voltage, for example, a screw or pin can be provided, which protrudes to a more or less extent into the range of a magnetic field and thus, for example, can be used for the zero balancing of the produced induction voltage. For the zero balance the screw or pin can be adjusted until a desired signal (for example, a signal balanced to zero) is produced. Preferably, for balancing or zero balancing no electrically conducting object to be detected is present. With the presence of an electrically conducting interference contour (such as for example due to metallic machine parts, built into/onto the sensor) the influence of the metallic interference contour can be reduced or eliminated with the zero balance. In this way sensors of the same type of construction can be manufactured for different application purposes (installed components), which can then however be balanced to zero according to the application or according to the interference contour.

Also, with an object of this nature a reference object can be created, so that with the presence of an identical or very similar electrically conducting object to be detected a zero signal is produced. This is, for example, particularly advantageous for the detection of certain coins. It is only when the electrically conducting object to be detected is more or less identical to the specified reference object that the application of the current pulse produces a zero signal or a predetermined signal and, if the electrically conducting object to be detected differs from the reference object, a signal differing from zero or a signal deviating from the predetermined signal is produced, which can be appropriately evaluated in order to discriminate electrically conducting objects to be detected, in particular coins. In this connection the induction voltage produced can be acquired at various times or only at a certain time after the application or switch-off of the current pulse.

If a reference object is provided as a constituent part of the device, then balancing or zero balancing by means of a screw or pin or an object suitable for balancing can occur, provided that an electrically conducting object to be detected is present, which is identical to the reference object and is arranged in the test position for objects to be detected later.

Instead of a coin other electrically conducting objects can also be compared with reference objects. This relates, for example, to objects, which are subject to abrasion or wear and their degree of abrasion or wear is to be acquired. To achieve this, an unabraded or unworn object can be compared with an object to be examined. For example, electrode caps, which are fitted to the electrodes of welding equipment and are cleaned from time to time, for example, by milling, by means of which they are consumed, can be measured and the degree of wear determined.

To influence the induction voltage produced, one or several further coils can be provided which can be used, for example, for producing a zero balance. The coils can be connected to the first and/or second coil in series or parallel or connected separately, for example, to a current source or short-circuited through a resistance or a circuit.

The third coil can also be realised in two parts, whereby the third coil then comprises two coil parts, from which, for example, one is assigned to the first coil and the other to the second coil. Here the two coil parts can be wound together on one coil former or also each on an individual coil former. The two coil parts are connected, for example, in series. The third coil can however also be realised as a single part, that is for example wound on one coil former.

Preferably, the device comprises a metal housing part or a full metal housing. Thus it is possible to employ the sensor also in environments with an aggressive ambient atmosphere such as for example acid or alkali-laden vapours.

The metal housing part or the full metal housing can be produced from any stainless steel or non-ferrous metal. Detection is also possible through stainless steel or non-ferrous metal, whereby there is no restriction to, for example, high ohmic metals. The front face of the sensor, i.e. the surface facing the object to be detected or its detection position, can be produced from any stainless steel or from non-ferrous metal. The detection of electrically conducting objects is also possible through materials of this nature. Depending on the application though, one or other metal may be preferred as the housing (part), whereby the selection of the metal can depend on the type of detection and also on the ambient conditions of the sensor (surrounding gases or liquids, temperature, pressure, etc.).

The device can in particular be formed as a proximity switch or for the detection of various materials, for coin detection or for the detection of the level of abrasion or wear on objects. As a proximity switch, the device can be installed subsurface, because the detected signals can be independent of the switching distance. Subsurface installation facilitates good protection of the device against damage.

Thus according to the invention a device, for example, such as a machine can be provided, which comprises a device for the detection of electrically conducting objects which is installed subsurface.

With the method for the detection of electrically conducting objects a current pulse is applied to a first and a second coil, whereby these coils produce magnetic fields with opposite polarity, by means of which the induction voltage produced in a third coil is acquired.

Instead it is also possible to apply a current pulse to the third coil and realise the acquisition of the induction voltage in the first and second coils. The induction voltage is preferably acquired in a time range during and/or after the application of the current pulse for the detection of the electrically conducting object. The current pulse comprises a step-shaped rise or a step-shaped fall, such as for example in the shape of a rectangular pulse.

Particular embodiments of the invention are explained based on the enclosed figures. The following are illustrated:

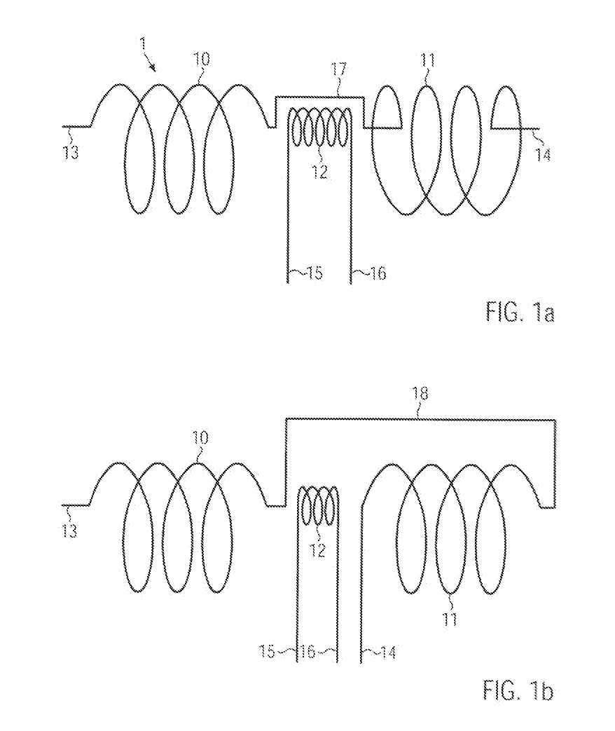

FIG. 1 various methods of connecting the first, second and third coils;

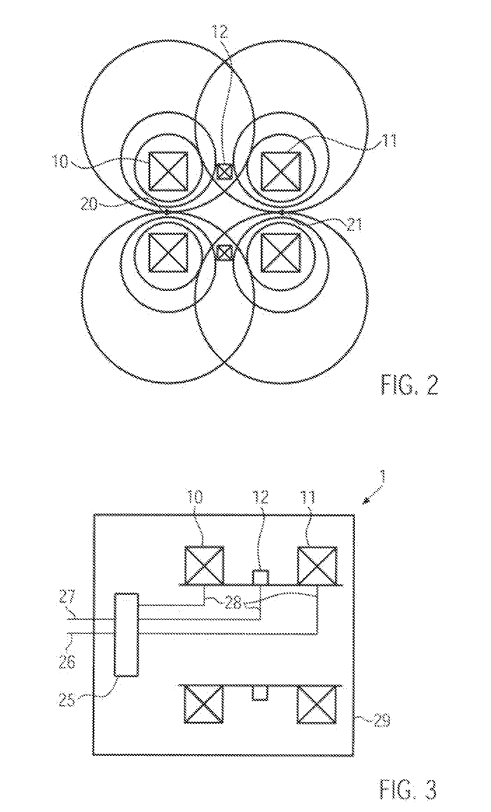

FIG. 2 the magnetic fields produced;

FIG. 3 a schematic illustration of the device;

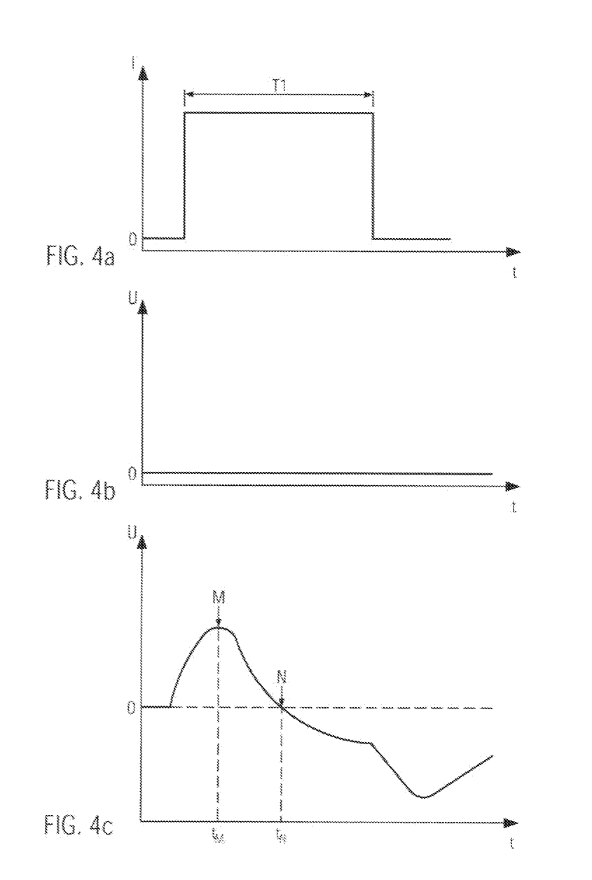

FIG. 4 current and voltage traces;

FIG. 5 a schematic illustration of the magnetic fields with the presence of an electrically conducting object;

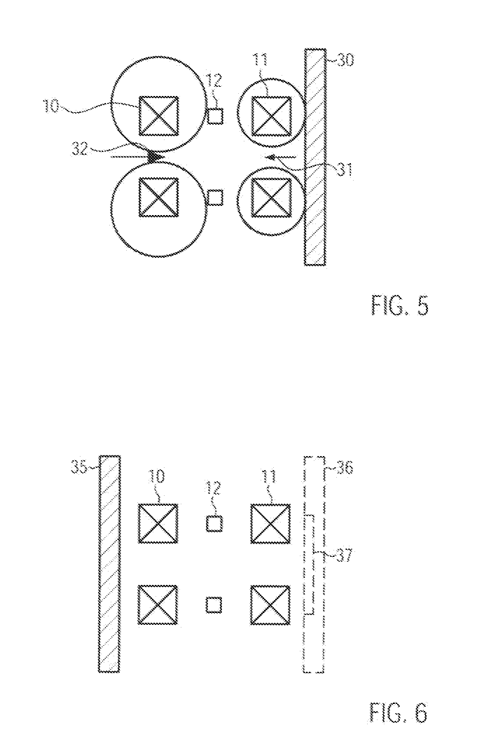

FIG. 6 a preferred variant of the device in a schematic illustration and

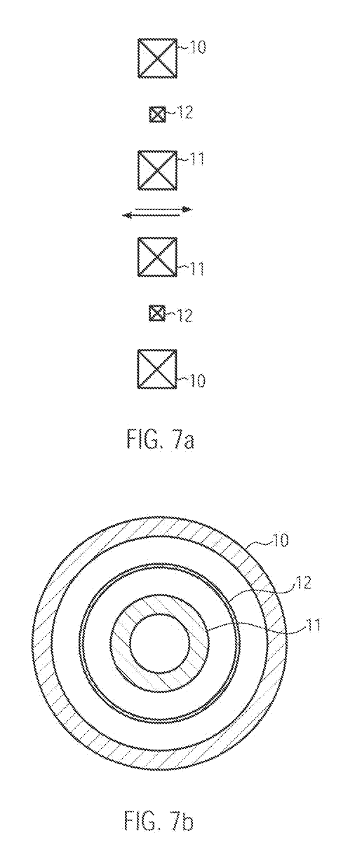

FIGS. 7a, 7b an alternative type of construction of the device.

FIG. 1a schematically illustrates a device 1 for the detection of an electrically conducting object. A first coil 10 and a second coil 11 are illustrated, which are connected together in series via the connection 17. The two coils are wound in the opposite sense so that a current, which flows from the terminal 13 to the terminal 14, produces a magnetic field orientated to the right and a magnetic field orientated to the left.

In the region between the two coils 10 and 11 a further coil 12 is arranged, with which a produced induction voltage can be acquired. This voltage can be tapped off between terminals 15 and 16.

The coil 12 is here arranged in the region which is permeated by the magnetic fields which can be produced by the coils 10 and 11.

In FIG. 1b a variant is shown in which the coils 10 and 11 are wound in the same direction, but due to a different connection 18, the current flows in different (opposing) directions in the two coils, so that here too magnetic fields are produced with opposite polarity when a current flows from terminal 13 to terminal 14. The coils can be connected to a power supply independently of one another. Here they are not then connected in series.

The number of windings in FIGS. 1a and 1b is only shown schematically. Preferably, the numbers of the turns on the coils 10 and 11 are identical or do not vary more than 5% or 1%. However, variants can also be provided in which the number of turns differs by up to 50% or 80%. The effect on the generated signals can be compensated by appropriate electronic compensation or by appropriate zero balancing.

Instead of applying a current to the terminals 13 and 14, a current for producing a magnetic field can be applied to the terminals 15 and 16 of the coil 12. In this case an induction voltage can be tapped off between terminals 13 and 14. For the case that the magnetic field of the coil 12 can propagate unrestricted and symmetrically, the induction voltage arising on the terminals 13 and 14 is zero due to the oppositely wound windings in FIG. 1a or the oppositely connected circuit in FIG. 1b.

The induction voltages produced in the coils 10 and 11 can also be acquired independently of one another. Here, the connection 17 or 18 is omitted and the induction voltages from the two coils are tapped off separately for each coil. The respective terminals of the two coils can be fed to a differential circuit, which exhibits or amplifies the difference of the induction voltages as an output signal, such as for example in the form of a differential amplifier.

FIG. 2 illustrates the device 1 in section. The coil 12 is arranged between the two coils 10 and 11. In FIG. 2 the magnetic field 20 produced by the coil 10 is illustrated as well as the magnetic field 21 produced by the coil 11 when current is passed through these coils.

As can be seen from FIG. 2, the magnetic fields of these two coils oppose one another so that when these magnetic fields are produced without further influences in the coil 12 an induction voltage which sums to zero is obtained.

The structure of a device 1 is illustrated schematically in FIG. 3. Apart from the coils 10, 11 and 12, an electronic means 25 is illustrated, which supplies the coils with corresponding terminals 28 with current or can tap off the corresponding induction voltages.

The electronic means 25 can be connected to external terminals 26, 27. These terminals can be used, for example, for the power supply of the device 1 or of the electronic means 25 or for outputting a measurement signal.

The coils 10, 11 and 12 can be wound on a coil former which is non-magnetic or also of soft magnetic material, such as for example a ferrite core.

Examples of the current and voltage traces are illustrated in FIG. 4. In FIG. 4a a rectangular current pulse is shown in which during the time T1 a current of a specified strength flows. This current flows, for example, between the terminals 13 and 14 of the coil arrangement in FIGS. 1a and 1b or also between the terminals 15 and 16 of FIGS. 1a and 1b.

Provided no electrically conducting object to be detected is present, a measurable induction voltage can arise, as is illustrated in FIG. 4b, namely a constant zero signal which is not influenced by the current pulse.

With the presence of an electrically conducting object an induction voltage arises, as illustrated in FIG. 4c as an example. During the current pulse in the time T1, the measured induction voltage U exhibits a temporal characteristic profile. This profile can, for example, be evaluated by the determination of a maximum M and a zero crossover N or also further characteristic points, such as the reversing point or similar feature. For example, for characterising this profile the time Δt can be determined, which gives the time interval between the maximum M and the zero crossover N, i.e. Δt=t_{N}−t_{M}. Also, the time from the start of the current pulse to the reversing point can be used for characterising the profile.

The induction voltage can also exhibit a minimum instead of a maximum, whereby, for example, Δt is given as the time interval between the minimum and a zero crossover.

Apart from the determination of Δt, as shown in FIG. 4c, the time from the application of the current pulse to the reaching of the maximum value M can also be determined or other characteristic times.

Also the absolute value at the maximum point of the voltage U can be considered for the evaluation of the induction voltage.

Also it is possible to determine the induction voltage at a fixed specified time after the start of the current pulse or at several such times and from the absolute values of this induction voltage or from the sign produced at various times, it is possible to draw conclusions about the characteristics of the electrically conducting object 30.

In FIG. 5 it is shown that the magnetic field 31 of the coil 11 can be influenced by the presence of an electrically conducting body 30 to be detected. As illustrated in FIG. 5, the arrow 32 is larger than the arrow 31. The arrow 32 represents the magnetic field produced by the coil 10. Due to the different influences of the magnetic fields 32 and 31 by the coils 10 and 11, the symmetry is broken, resulting in an induction voltage being produced in the coil 12. The induction voltage produced in the coil 12 exhibits typical characteristics (in particular characteristic temporal traces) which provide information on the condition of the object 30.

As already previously mentioned, instead of the production of the magnetic fields by the coils 10 and 11, the magnetic field can also be produced by the coil 12, whereby this magnetic field turns out to be asymmetrical due to the presence of the object 30, so that in the coil 11 an induction voltage different from that of coil 10 is produced, which with appropriate connection (refer to FIGS. 1a, 1b) does not lead to complete compensation or cancellation of the two induction voltages, but rather to an induction voltage differing from zero.

In FIG. 6 the device 1 for the detection of an electrically conducting object is illustrated, whereby a reference object 35 is provided to the left of the coil arrangement. If an identical electrically conducting object 36 or one of almost the same type is arranged at the right end of the coil arrangement, then on applying a current pulse to the coils 10 and 11, an induction voltage is produced by the coil 12 which is equal to zero. If however a different type of electrically conducting object, such as for example is illustrated by the broken line 37, is placed against the coil arrangement, an induction voltage differing from zero is produced, which indicates that the electrically conducting object to be detected is not identical or similar to the electrically conducting object 35.

Through the specification of an electrically conducting reference object 35, an electrically conducting object 36 to be examined can be compared for a plurality of characteristics with respect to the reference object. Each deviation in the material composition, size, etc. leads to an induction voltage differing from zero. With differences in the objects 35 and 36 also temporal characteristic traces in the induction voltage can occur. The induction voltage can also exhibit maxima and/or minima and/or zero crossovers or reversing points, which can be detected and evaluated to quantify the difference between the two objects. Here, both time intervals between maxima and/or minima and/or zero crossovers and/or reversing points and/or the values of the voltage at these points can be evaluated. Also the time of occurrence of a maximum/minimum/zero crossover/reversing point can be evaluated from the application of the current pulse.

If the two objects 35 and 36 are identical and symmetrically arranged with respect to the coil arrangement and if the coils 35 are identical and symmetrically arranged, then with the application of a current pulse of the same amplitude to both coils, a temporally constant zero signal is obtained. Any deviation from this indicates that there is a difference between the two objects. Instead of producing a zero signal, the coil arrangement or the current supply of the coils can be such that also with identical objects 35, 36, a temporal trace of the induction voltage is produced which differs from zero (reference). Any further deviation from a reference of this nature of an acquired induction voltage then indicates however a difference in the objects.

Through the comparison of two objects 35, 36 a forgery check of coins or also the determination of a degree of abrasion or wear on abraded or worn objects is possible. Thus, for example, the degree of wear on welding electrode caps can also be examined.

As previously mentioned, a measurement process can be carried out in that the current is applied to the coil 12 and the induction voltage determined which arises in the coils 10 and 11.

FIGS. 7a and 7b illustrate an alternative type of construction for the device for the detection of electrically conducting objects in which the coil 11 is provided within the coil 10 and the coil 12 is arranged between the coils 10 and 11. The various coils are here arranged one behind the other in a radially outwards direction. In this respect the second and third coils can be provided completely or partially within the spatial region surrounded by the first coil. FIG. 7a shows a section through the coil arrangement illustrated in FIG. 7b in a plan view.

Also in this configuration, detection of electrically conducting objects is possible with the same differentiation methods.

In all the figures the coils 10, 11 and 12 can also be round or angular, so that a winding is, for example, formed circular or rectangular or square.

1. Device for the detection of electrically conducting objects with:
a first and a second coil, which can produce magnetic fields simultaneously with opposite polarity and
a third coil, which is arranged in the region of the opposing magnetic fields, and
an electronic means, which, during and/or after the supply of the first and second coils with a current pulse, acquires an induction voltage in the third coil, or which acquires an induction voltage in the first and second coils during the supply of the third coil with a current pulse,
so that an electrically conducting object when present in the range of one of the magnetic fields, produces a detectable signal in the acquired induction voltage,
wherein the current pulse comprises a step-shaped rise and/or a step-shaped fall, such as for example in the shape of a rectangular pulse.

2. Device according to claim 1, characterised in that the first and second coils are wound in the opposite direction or the same direction.

3. Device according to claim 1, characterised in that the current pulse has the shape of a rectangular pulse with a duration between 0.1 ns and 1 ms, such as approximately between 1 μs and 50 μs.

4. Device according to one of the claim 1, characterised in that the induction effects produced in the third coil by the first and second coil compensate at least partially, preferably by at least 90% or 99%, whereby preferably the induction voltages essentially sum to zero when the electrically conducting object to be detected is not present
or
the induction voltages produced by the third coil in the first and second coils are acquired such that these two induction voltages mutually compensate, at least partially, preferably up to 90% or 99%, wherein preferably the two induction voltages essentially sum to zero when the electrically conducting object to be detected is not present.

5. Device according to one of the claim 1, characterised in that the electronic means is formed such that the course of the produced induction voltage is acquired at various times.

6. Device according to claim 5, characterised in that the electronic means is formed such that the point in time of a maximum (M) and/or a minimum and/or a zero crossover (N) and/or a reversing point of the produced induction voltage is determined, wherein preferably the temporal interval (Δt) is determined between a maximum or minimum and a zero crossover or between the start of the current pulse and a maximum or a minimum or a zero crossover.

7. Device according to one of the claim 1, characterised in that in the region of the first or second coil a metallic conducting object is provided as a constituent part of the device, with which for example balancing of the produced induction voltage is possible or specification of a reference object or the influence of an interference contour can be reduced or balanced to zero.

8. Device according to one of the claim 1, characterised in that one or several further coils are provided, which can have influence on the produced induction voltage.

9. Device according to one of the claim 1, characterised in that the device comprises a metal housing part or a full metal housing, wherein the full metal housing at least encloses the first, second and third coils and possibly part of the electronic means or the complete electronic means wherein the metal housing part or the full metal housing comprises non-ferrous metal or stainless steel or is manufactured from it.

10. Device according to one of the claim 1, characterised in that the device is formed as a proximity switch or as a device for the detection of various materials, as a coin detection device or as a device for acquiring a level of abrasion or wear.

11. Method for the detection of electrically conducting objects with the steps:
application of a current pulse on a first and a second coil, wherein these coils produce magnetic fields with opposite polarity and the acquisition of an induction voltage thus produced in a third coil
or
application of a current pulse in a third coil and the acquisition of the induction voltage thus produced in a first and second coil, and
evaluation of the acquired induction voltage in a time range during the application of the current pulse for the detection of the electrically conducting object,
wherein the current pulse comprises a step-shaped rise and/or a step-shaped fall, such as for example in the shape of a rectangular pulse.
